(19) United States
(12) Patent Application Publication
(10) Pub. No.: US 2025/0081489 A1
(43) Pub. Date: Mar. 6, 2025

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventors: Masato HAYASHI, Komatsu Ishikawa (JP); Tatsuo NAIJO, Kanazawa Ishikawa (JP)

(21) Appl. No.: 18/601,470

(22) Filed: Mar. 11, 2024

(30) Foreign Application Priority Data
Sep. 6, 2023 (JP) 2023-144803

(51) Int. Cl. H01L 29/739; H01L 29/66

(52) U.S. Cl. CPC H10D 12/481; H10D 12/038

(57) ABSTRACT

A semiconductor device includes a first electrode, a second electrode, a first semiconductor layer, a second semiconductor layer, and a third semiconductor layer. A concentration of the first impurity has a maximum value at a first position in a first direction inside the first semiconductor layer. The first direction is from the first electrode toward the second electrode. A concentration of proton is greater than the concentration of the first impurity in the second semiconductor layer. The concentration of the first impurity is greater than the concentration of proton in the third semiconductor layer. The concentration of the first impurity is greater than the concentration of proton in at least a portion of the first semiconductor layer at the second semiconductor layer side. The concentration of proton has a maximum value at a second position positioned at a side of the first position opposite to the first direction.

### CROSS-REFERENCE TO RELATED APPLICATIONS

This application is based upon and claims the benefit of priority from Japanese Patent Application No. 2023-144803, filed on Sep. 6, 2023; the entire contents of which are incorporated herein by reference.

### FIELD

Embodiments described herein relate generally to a semiconductor device and a method for manufacturing a semiconductor device.

### BACKGROUND

It is desirable for a semiconductor device for power control to have a certain short-circuit withstand capacity when a load is short-circuited so that the semiconductor device is not damaged before a protection circuit operates.

### BRIEF DESCRIPTION OF THE DRAWINGS

FIG. 1A is a top view showing a semiconductor device according to a first embodiment; and FIG. 1B is a cross-sectional view of the semiconductor device according to the first embodiment;

FIG. 2 shows concentration profiles along the Z-direction of the impurities according to the first embodiment, in which the horizontal axis is the Z-direction position, and the vertical axis is the concentrations of the impurities;

FIGS. 3 to 9 are cross-sectional views showing the method for manufacturing the semiconductor device according to the first embodiment;

FIG. 10 shows concentration profiles along the Z-direction of impurities according to a first modification of the first embodiment, in which the horizontal axis is the Z-direction position, and the vertical axis is the concentrations of the impurities;

FIG. 11 shows concentration profiles along the Z-direction of impurities according to a second modification of the first embodiment, in which the horizontal axis is the Z-direction position, and the vertical axis is the concentrations of the impurities;

FIG. 12 is a cross-sectional view showing a semiconductor device according to a second embodiment;

FIG. 13 shows concentration profiles along the Z-direction of the impurities according to the second embodiment, in which the horizontal axis is the Z-direction position, and the vertical axis is the concentrations of the impurities;

FIG. 14 shows concentration profiles along the Z-direction of impurities according to a modification of the second embodiment, in which the horizontal axis is the Z-direction position, and the vertical axis is the concentrations of the impurities;

FIG. 15 is a graph showing the effects of the proton profile on the short-circuit withstand capacity, in which the horizontal axis is the position at which the proton concentration has a maximum value in the Z-direction, and the vertical axis is the result of a short-circuit withstand capacity test; and

FIG. 16 shows concentration profiles along the Z-direction of the impurities in a test example, in which the horizontal axis is the Z-direction position, and the vertical axis is the concentrations of the impurities.

### DETAILED DESCRIPTION

In general, according to one embodiment, a semiconductor device includes a first electrode, a second electrode, a first semiconductor layer provided between the first electrode and the second electrode, a second semiconductor layer located at a first-direction side of the first semiconductor layer, and a third semiconductor layer located at the first-direction side of the second semiconductor layer. The first semiconductor layer includes a first impurity and protons. The first impurity and the protons form donors. The first semiconductor layer is of an n-conductivity type. A concentration of the first impurity has a maximum value at a first position in a first direction inside the first semiconductor layer. The first direction is from the first electrode toward the second electrode. The second semiconductor layer includes the first impurity and protons. A concentration of proton is greater than the concentration of the first impurity in the second semiconductor layer. The second semiconductor layer is of the n-conductivity type. The third semiconductor layer includes the first impurity. The concentration of the first impurity is greater than the concentration of proton in the third semiconductor layer. The third semiconductor layer is of the n-conductivity type. The concentration of the first impurity is greater than the concentration of proton in at least a portion of the first semiconductor layer at the second semiconductor layer side. The concentration of proton has a maximum value at a second position in the first direction. The second position is positioned at a side of the first position opposite to the first direction.

In general, according to one embodiment, a method for manufacturing a semiconductor device, the method includes implanting a first impurity into a semiconductor member in a first direction from a first surface side of the semiconductor member so that a first impurity concentration has a maximum value at a first position in the first direction inside the semiconductor member. The first impurity forms donors. The semiconductor member is of an n-conductivity type. The method includes providing an absorber at the first surface side of the semiconductor member. The method includes implanting protons into the semiconductor member in the first direction via the absorber so that a concentration of proton has a maximum value at a second position in the first direction, the second position being positioned at a side of the first position opposite to the first direction. The method includes removing the absorber.

### First Embodiment

### Semiconductor Device

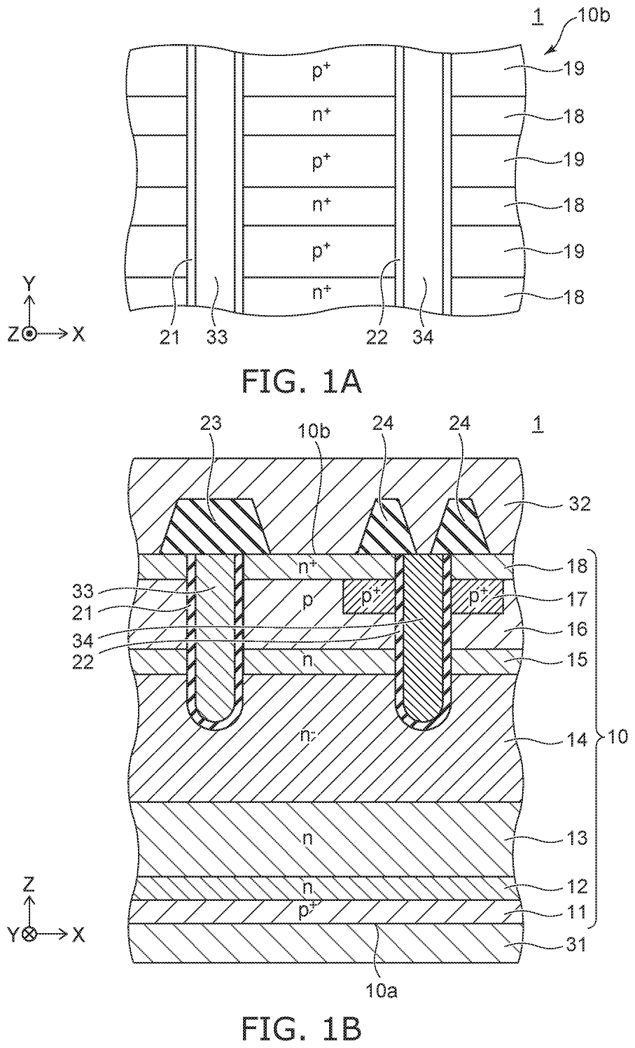

FIG. 1A is a top view showing a semiconductor device according to the embodiment; and FIG. 1B is a cross-sectional view of the semiconductor device according to the embodiment.

In FIG. 1A, an emitter electrode and an insulating member that are described below are not illustrated, and the upper surface of a semiconductor part is shown.

The semiconductor device 1 according to the embodiment is, for example, a power semiconductor for power control, and is, for example, an IGBT (Insulated Gate Bipolar Transistor).

As shown in FIGS. 1A and 1B, the semiconductor device 1 includes a semiconductor part 10. The semiconductor part 10 is made of a semiconductor material and is made of, for example, single-crystal silicon (Si). Each portion of the semiconductor part 10 is set to an n- or p-conductivity type by introducing an impurity that forms donors or acceptors to each portion.

The semiconductor device 1 includes a collector electrode 31, an emitter electrode 32, a gate electrode 33, and a dummy gate electrode 34. One collector electrode 31 and one emitter electrode 32 are included. Multiple gate electrodes 33 and multiple dummy gate electrodes 34 are included. The collector electrode 31 contacts a lower surface 10a of the semiconductor part 10; and the emitter electrode 32 contacts an upper surface 10b of the semiconductor part 10. The gate electrode 33 and the dummy gate electrode 34 are located inside the semiconductor part 10 and extend in one direction.

An XYZ orthogonal coordinate system is employed for convenience of description in the specification hereinbelow. The direction from the collector electrode 31 toward the emitter electrode 32 is taken as a “Z-direction” (a first direction); the direction in which the gate electrode 33 and the dummy gate electrode 34 extend is taken as a “Y-direction”; and a direction orthogonal to the Z-direction and Y-direction is taken as an “X-direction”. Although the Z-direction also is called “up/upward”, and the opposite direction (the −Z direction) also is called “down/downward”, these expressions are for convenience and are independent of the direction of gravity.

The semiconductor part 10 includes a p⁺-type collector layer 11 (a fourth semiconductor layer), a thin n-type buffer layer 12 (a first semiconductor layer), a thick n-type buffer layer 13 (a second semiconductor layer), an n⁻-type base layer 14 (a third semiconductor layer), an n-type barrier layer 15, a p-type base layer 16 (a fifth semiconductor layer), a p⁺-type diffusion layer 17, an n⁺-type emitter layer 18 (a sixth semiconductor layer), and a p⁺-type contact layer 19.

The p⁺-type collector layer 11 forms the lower surface 10a of the semiconductor part 10. The p⁺-type collector layer 11 is located on the collector electrode 31 and contacts the collector electrode 31. The p⁺-type collector layer 11, the thin n-type buffer layer 12, the thick n-type buffer layer 13, the n⁻-type base layer 14, the n-type barrier layer 15, and the p-type base layer 16 are stacked in this order along the Z-direction and are connected to each other. In the specification, “connected” 20 refers to an electrical connection.

The n⁺-type emitter layer 18 and the p⁺-type contact layer 19 are located on the p-type base layer 16 and extend in the X-direction. The n⁺-type emitter layer 18 and the p⁺-type contact layer 19 are alternately arranged along the Y-direction. The n⁺-type emitter layer 18 and the p⁺-type contact layer 19 form the upper surface 10b of the semiconductor part 10.

The p⁺-type diffusion layer 17 is located at the vicinity of the dummy gate electrode 34 between the p-type base layer 16 and the n⁺-type emitter layer 18 and between the p-type base layer 16 and the p⁺-type contact layer 19, and extends in the Y-direction.

The emitter electrode 32 is located on the n⁺-type emitter layer 18 and on the p⁺-type contact layer 19. The n⁺-type emitter layer 18 and the p⁺-type contact layer 19 are connected to the emitter electrode 32.

The gate electrode 33 and the dummy gate electrode 34 extend downward, i.e., toward the collector electrode 31 side, from the upper surface 10b side, i.e., the emitter electrode 32 side, of the semiconductor part 10. The gate electrode 33 and the dummy gate electrode 34 pass by the sides of the p-type base layer 16 and the n-type barrier layer 15 from the upper surface of the n⁺-type emitter layer 18 and the upper surface of the p⁺-type contact layer 19 and reach the interior of the n⁻-type base layer 14. The dummy gate electrode 34 also passes by the side of the p⁺-type diffusion layer 17. The gate electrode 33 and the dummy gate electrode 34 may be alternately arranged one at a time along the X-direction; one dummy gate electrode 34 may be provided for multiple gate electrodes 33; or one gate electrode 33 may be provided for multiple dummy gate electrodes 34. The dummy gate electrode 34 may not be included.

The semiconductor device 1 includes a gate insulating film 21, a dummy gate insulating film 22, a gate insulating member 23, and a dummy gate insulating member 24. The gate insulating film 21 is located between the gate electrode 33 and the semiconductor part 10 and insulates the gate electrode 33 from the semiconductor part 10. The dummy gate insulating film 22 is located between the dummy gate electrode 34 and the semiconductor part 10 and insulates the dummy gate electrode 34 from the semiconductor part 10.

The gate insulating member 23 and the dummy gate insulating member 24 are located on the semiconductor part 10. The gate insulating member 23 is located between the gate electrode 33 and the emitter electrode 32 and insulates the gate electrode 33 from the emitter electrode 32. The dummy gate insulating member 24 is arranged to cover the upper end portion of the dummy gate insulating film 22 and protect the upper end portion of the dummy gate insulating film 22. A portion of the emitter electrode 32 is located between the dummy gate insulating members 24 and is connected to the dummy gate electrode 34. Therefore, an emitter potential is applied to the dummy gate electrode 34.

### Impurity Concentration Profiles at Collector Side of Semiconductor Part

Impurity concentration profiles along the Z-direction of a portion of the semiconductor part 10 at the collector side, i.e., the p⁺-type collector layer 11, the thin n-type buffer layer 12, the thick n-type buffer layer 13, and the n⁻-type base layer 14, will now be described.

The semiconductor part 10 includes protons (H⁺) and phosphorus (P) as impurities that form donors, and includes boron (B) as an impurity that forms acceptors. A proton is a hydrogen cation. Impurities that form donors other than protons are not limited to phosphorus and may be other impurities such as arsenic (As), antimony (Sb), etc. Impurities that form acceptors are not limited to boron and may be other impurities such as gallium (Ga), indium (In), etc.

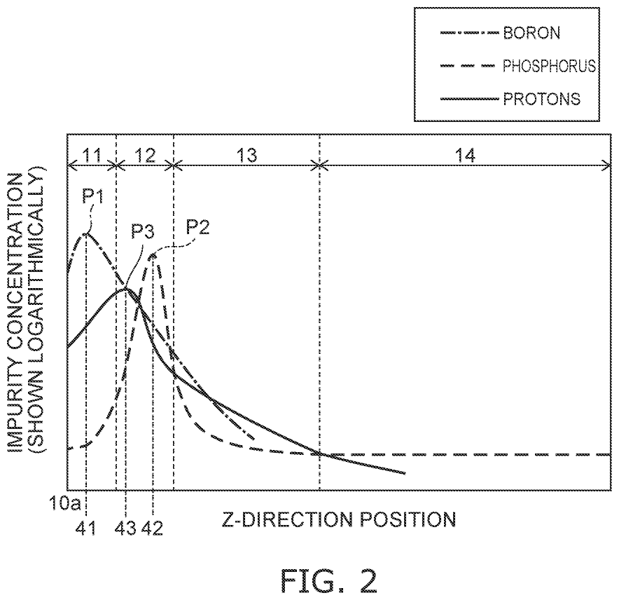

FIG. 2 shows concentration profiles along the Z-direction of the impurities according to the embodiment, in which the horizontal axis is the Z-direction position, and the vertical axis is the concentrations of the impurities.

FIG. 2 is a conceptual view qualitatively showing features of the concentration profiles. Actual measurement results are described in an example below. The vertical axis of FIG. 2 is shown logarithmically.

First, the general concept of each layer will be described.

As shown in FIGS. 1B and 2, the thickness, i.e., the Z-direction length, of the thick n-type buffer layer 13 is greater than the thickness of the thin n-type buffer layer 12. The average value of the carrier concentration of the thick n-type buffer layer 13 is less than the average value of the carrier concentration of the thin n-type buffer layer 12. The thickness of the n⁻-type base layer 14 is greater than the thickness of the thick n-type buffer layer 13. The average value of the carrier concentration of the n⁻-type base layer 14 is less than the average value of the carrier concentration of the thick n-type buffer layer 13. The thickness of the n-type barrier layer 15 is less than the thickness of the n⁻-type base layer 14. The average value of the carrier concentration of the n-type barrier layer 15 is greater than the average value of the carrier concentration of the n⁻-type base layer 14.

The concentration profiles of the impurities will now be described.

As shown in FIG. 2, the boron concentration profile starts from the lower surface 10a of the semiconductor part 10, increases in the +Z direction, and has a peak P1 inside the p⁺-type collector layer 11. In the range shown in FIG. 2, the boron concentration has a maximum value at the peak P1. Accordingly, a position 41 in the Z-direction at which the boron concentration has the maximum value is aligned with the position of the peak P1. Inside the p⁺-type collector layer 11, the boron concentration is greater than the total value of the phosphorus concentration and the proton concentration.

The phosphorus concentration profile starts from the lower surface 10a of the semiconductor part 10, increases in the +Z direction, and has a peak P2 inside the thin n-type buffer layer 12. The phosphorus concentration has a maximum value at the peak P2 and monotonously decreases in the +Z direction and −Z direction from the peak P2 inside the p⁺-type collector layer 11, inside the thin n-type buffer layer 12, and inside the thick n-type buffer layer 13. “Monotonously decrease” means that the substantial concentration of the impurity decreases along one direction, without considering fine increases or reductions caused by measurement noise.

The phosphorus concentration is substantially constant inside the n⁻-type base layer 14. Accordingly, in the range shown in FIG. 2, a position 42 in the Z-direction at which the phosphorus concentration has a maximum value is aligned with the position of the peak P2. The total value of the phosphorus concentration and the proton concentration is greater than the boron concentration in the thin n-type buffer layer 12, in the thick n-type buffer layer 13, and in the n⁻-type base layer 14.

The proton concentration profile starts from the lower surface 10a of the semiconductor part 10, increases in the +Z direction, and has a peak P3 inside the thin n-type buffer layer 12. The proton concentration has a maximum value at the peak P3 and monotonously decreases in the +Z direction and −Z direction from the peak P3. Accordingly, a position 43 in the Z-direction at which the proton concentration has the maximum value is aligned with the position of the peak P3. The position 43 in the Z-direction at which the proton concentration has the maximum value is positioned at the −Z direction side, that is, at the lower surface 10a side of the semiconductor part 10, with respect to the position 42 at which the phosphorus concentration has the maximum value.

The relationships of the impurity concentrations will now be described by focusing on each layer.

The boron concentration is greater than the total value of the phosphorus concentration and the proton concentration in the p⁺-type collector layer 11. The peak P1 of boron is positioned inside the p⁺-type collector layer 11.

The total value of the phosphorus concentration and the proton concentration is greater than the boron concentration in the thin n-type buffer layer 12. The phosphorus concentration is greater than the proton concentration in at least a portion of the thin n-type buffer layer 12 at the thick n-type buffer layer 13 side. The peak P2 of phosphorus and the peak P3 of the protons are positioned inside the thin n-type buffer layer 12. The peak P3 of the protons is positioned at the −Z direction side of the peak P2 of phosphorus. The interface between the p⁺-type collector layer 11 and the thin n-type buffer layer 12 is the position at which the magnitude relationship of the concentration of the impurities that forms acceptors and the concentration of the impurities that form donors inverts. In the p⁺-type collector layer 11, the concentration of the impurities that forms acceptors is greater than the concentration of the impurities that form donors; and in the thin n-type buffer layer 12, the concentration of the impurities that form donors is greater than the concentration of the impurities that forms acceptors.

Inside the thick n-type buffer layer 13, the total value of the phosphorus concentration and the proton concentration is greater than the boron concentration; and the proton concentration is greater than the phosphorus concentration. The interface between the thin n-type buffer layer 12 and the thick n-type buffer layer 13 is the position at which the magnitude relationship of the phosphorus concentration and the proton concentration inverts. In at least a portion of the thin n-type buffer layer 12 at the thick n-type buffer layer 13 side, the phosphorus concentration is greater than the proton concentration; and in the thick n-type buffer layer 13, the proton concentration is greater than the phosphorus concentration. As described above, the overall carrier concentration of the thick n-type buffer layer 13 is less than the carrier concentration of the thin n-type buffer layer 12. No peak of the impurity concentration is present inside the thick n-type buffer layer 13; and the impurity concentrations monotonously decrease in the +Z direction.

Inside the n⁻-type base layer 14, the total value of the phosphorus concentration and the proton concentration is greater than the boron concentration; and the phosphorus concentration is greater than the proton concentration. As described above, the overall carrier concentration of the n⁻-type base layer 14 is less than the carrier concentration of the thick n-type buffer layer 13. Inside the n⁻-type base layer 14, no impurity concentration peak is present, and the carrier concentration is substantially constant in the Z-direction. “Carrier concentration” refers to the effective impurity concentration contributing to the conduction of the semiconductor material, and when both an impurity that forms donors and an impurity that forms acceptors are included in one portion, refers to the difference of the concentration excluding the cancelled portion.

### Method for Manufacturing

A method for manufacturing the semiconductor device according to the embodiment will now be described.

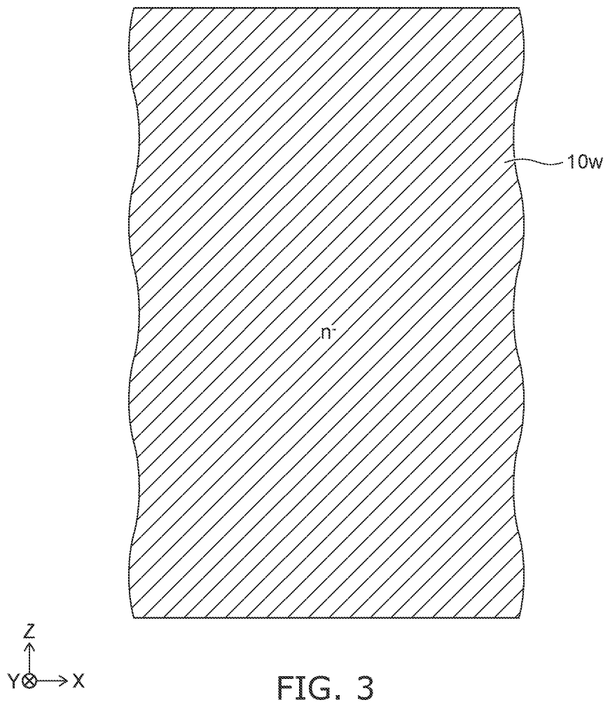

FIGS. 3 to 9 are cross-sectional views showing the method for manufacturing the semiconductor device according to the embodiment.

First, a semiconductor wafer 10w is prepared as shown in FIG. 3. The semiconductor wafer 10w is made of, for example, single-crystal silicon, includes an impurity that forms donors, e.g., phosphorus, uniformly and over the entirety, and is of the n⁻-conductivity type.

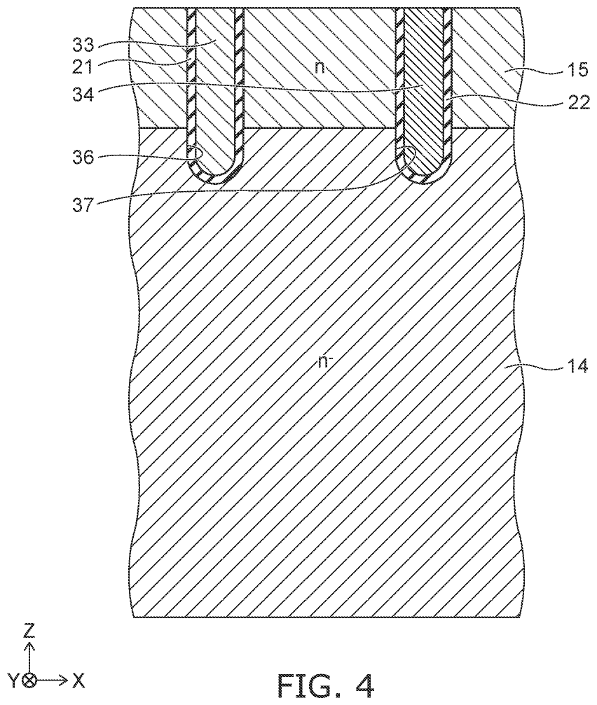

Then, as shown in FIG. 4, the n-type barrier layer 15 is formed by ion-implanting an impurity into the upper surface 10b side of the semiconductor wafer 10w. The portion of the semiconductor wafer 10w into which the impurity is not ion-implanted is used to form the n⁻-type base layer 14.

Continuing, a gate trench 36 and a dummy gate trench 37 are formed from the upper surface 10b side of the semiconductor wafer 10w. Then, by performing thermal oxidation treatment, the gate insulating film 21 is formed on the inner surface of the gate trench 36; and the dummy gate insulating film 22 is formed on the inner surface of the dummy gate trench 37. Then, by depositing a conductive material such as polysilicon or the like on the entire surface, the gate electrode 33 is formed in the gate trench 36; and the dummy gate electrode 34 is formed in the dummy gate trench 37. Then, the conductive material that is deposited on the upper surface 10b of the semiconductor wafer 10w is removed.

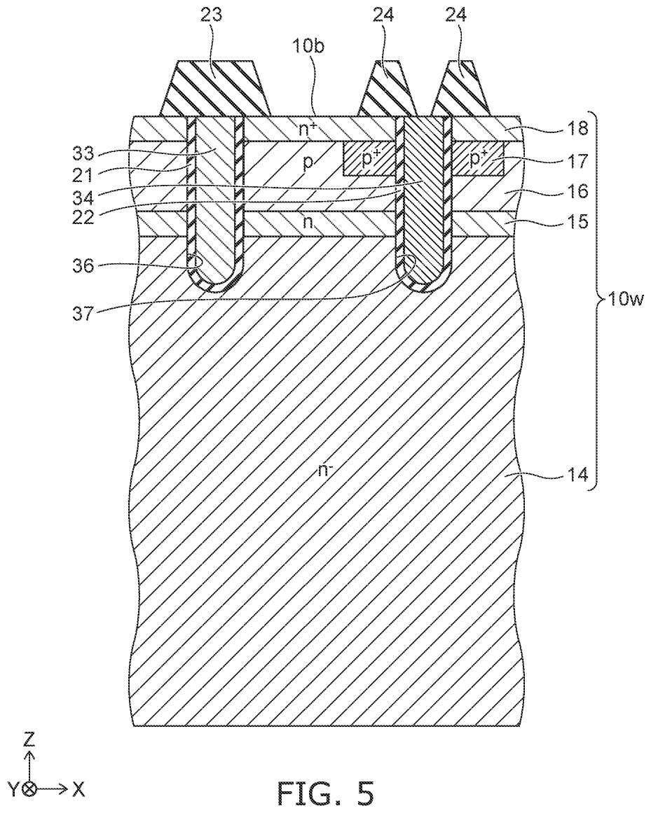

Continuing as shown in FIG. 5, the p-type base layer 16, the p⁺-type diffusion layer 17, the p⁺-type contact layer 19 (see FIG. 1A), and the n⁺-type emitter layer 18 are formed by sequentially ion-implanting impurities into the upper surface 10b side of the semiconductor wafer 10w. Then, the gate insulating member 23 and the dummy gate insulating member 24 are formed by selectively forming silicon oxide on the upper surface 10b of the semiconductor wafer 10w. Thus, the upper structure of the IGBT is formed in the upper portion of the semiconductor wafer 10w.

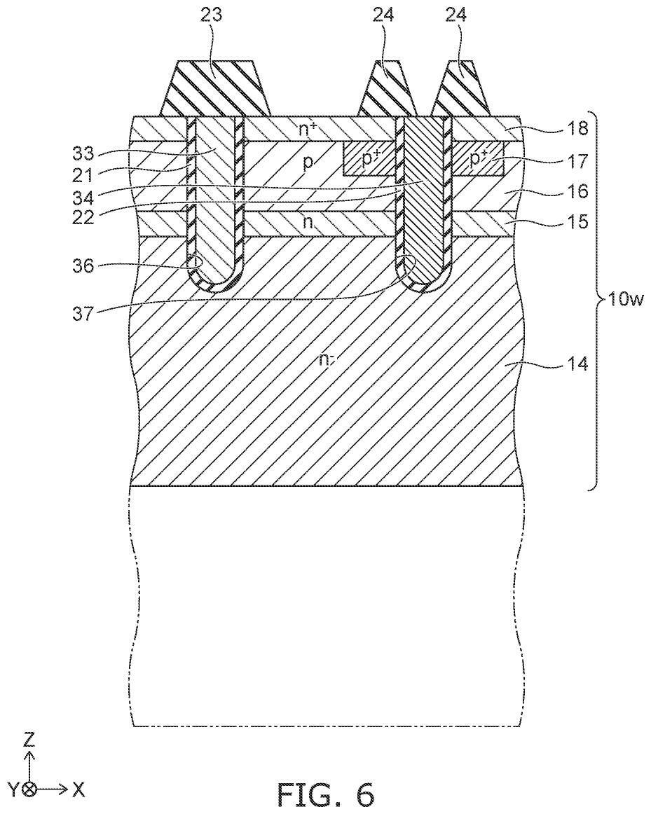

Then, as shown in FIG. 6, the semiconductor wafer 10w is thinned by polishing from the lower surface side.

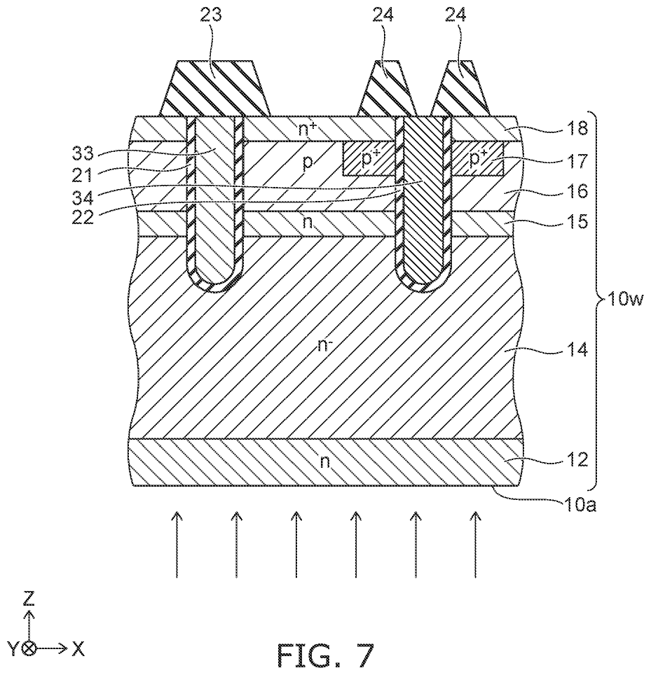

Continuing as shown in FIG. 7, phosphorus is ion-implanted from the lower surface 10a side of the semiconductor wafer 10w. At this time, the phosphorus concentration profile has the peak P2 inside the semiconductor wafer 10w (see FIG. 2). The thin n-type buffer layer 12 is formed thereby.

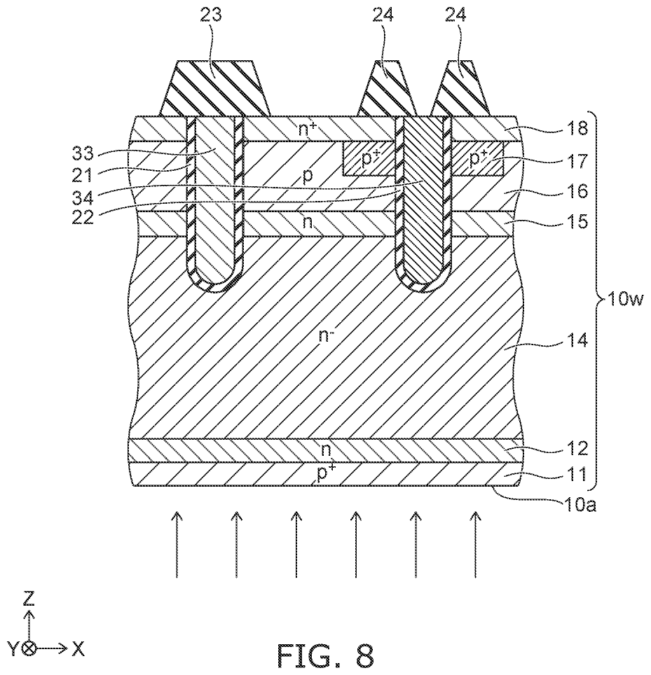

Then, as shown in FIG. 8, boron is ion-implanted from the lower surface 10a side of the semiconductor wafer 10w. At this time, the boron concentration profile has the peak P1 at a position at the −Z direction side of the peak P2 inside the semiconductor wafer 10w (see FIG. 2). The p⁺-type collector layer 11 is formed thereby.

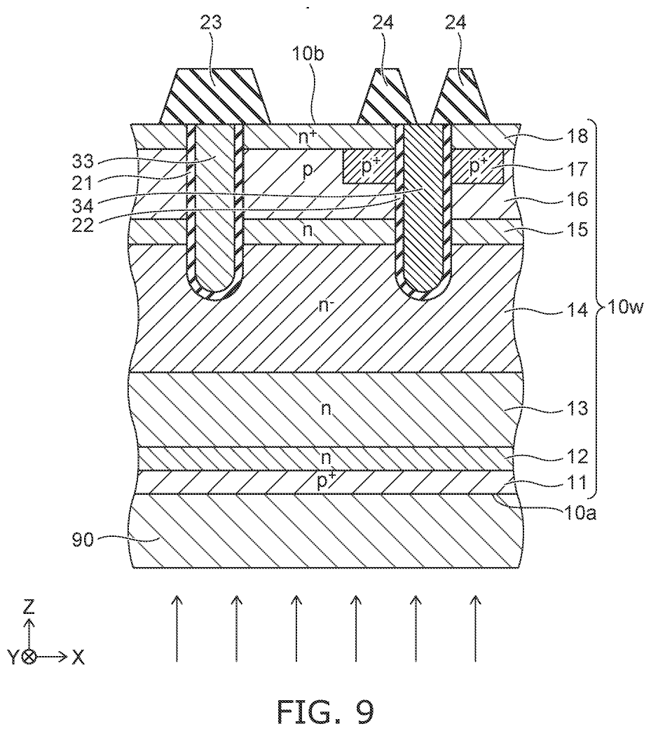

Continuing as shown in FIG. 9, an absorber 90 is provided on the lower surface 10a of the semiconductor wafer 10w. For example, the absorber 90 is formed by stacking an aluminum foil. Then, protons, i.e., hydrogen cations, are implanted into the semiconductor wafer 10w in the Z-direction via the absorber 90 by, for example, a cyclotron. The protons reach a deep position inside the semiconductor wafer 10w because protons are smaller than phosphorus. On the other hand, because the protons are implanted via the absorber 90, some of the protons remain inside the absorber 90. As a result, the peak P3 of the protons (see FIG. 2) is positioned at the −Z direction side of the peak P2 of phosphorus. The thick n-type buffer layer 13 is formed thereby. In the silicon included in the thick n-type buffer layer 13, the protons are defects and are impurities that form donors.

In an example, the implantation conditions of the protons are set so that the peak P3 of the proton concentration profile is positioned at the lower surface 10a of the semiconductor wafer 10w. However, there is a possibility that the actual position of the peak P3 may shift in the +Z direction or −Z direction from the lower surface 10a. FIG. 2 above shows an example in which the peak P3 has shifted in the +Z direction side, that is, inside the semiconductor wafer 10w, from the lower surface 10a. As a result, the peak P3 of the protons is positioned inside the thin n-type buffer layer 12 at the −Z direction side of the peak P2 of phosphorus. Subsequently, the absorber 90 is removed.

Then, the implanted impurities are activated by performing heat treatment. The heat treatment activates the implanted protons to become lattice defects that function as donors. The n-type defect layer functions as an n-type conductive layer and is therefore used to form the thick n-type buffer layer 13.

Continuing as shown in FIGS. 1A and 1B, the collector electrode 31 and the emitter electrode 32 are formed. Then, the semiconductor wafer 10w is singulated by dicing. The semiconductor device 1 is manufactured thereby.

### Effects

Effects of the embodiment will now be described.

The semiconductor device 1 according to the embodiment includes the thick n-type buffer layer 13 in addition to the thin n-type buffer layer 12. As a result, elongation of the depletion layer at turn-off of the semiconductor device 1 can be suppressed. Therefore, a rapid discharge of carriers due to the depletion layer reaching the thin n-type buffer layer 12 can be suppressed, and LC resonance of the capacitance (C) of the depletion layer inside the device and a parasitic inductance (L) outside the device can be suppressed. As a result, voltage oscillations due to switching can be suppressed.

According to the embodiment, the position 43 at which the proton concentration has a maximum value is positioned at the −Z direction side, i.e., the collector electrode 31 side, of the position 42 at which the phosphorus concentration has a maximum value. The short-circuit withstand capacity of the semiconductor device 1 can be improved thereby.

When the semiconductor device 1 is in the on-state, a large current flows in the semiconductor device 1 when a short-circuit occurs for some reason in a load connected to the semiconductor device 1. Normally, in such a case, an external protection circuit operates to block the current flowing in the semiconductor device 1; however, it takes time from the short-circuit of the load until the protection circuit operates. It is desirable for the semiconductor device 1 not to undergo breakdown during this time. The short-circuit withstand capacity refers to a level such that the semiconductor device 1 does not undergo breakdown under such conditions.

According to the embodiment, the position 43 at which the proton concentration has a maximum value is positioned at the −Z direction side of the position 42 at which the phosphorus concentration has a maximum value, and so the transport efficiency at the lower surface 10a vicinity of the semiconductor part 10 is increased, and more holes are injected. As a result, the electric field at the lower surface 10a vicinity is reduced, and the short-circuit withstand capacity is increased.

If the position 43 at which the proton concentration has a maximum value is positioned at the same position as, or at the +Z direction side, i.e., the emitter electrode 32 side, of the position 42 at which the phosphorus concentration has a maximum value, the transport efficiency at the lower surface 10a vicinity is reduced, fewer holes are injected, and the electric field of the lower surface 10a vicinity is increased. As a result, the short-circuit withstand capacity is reduced.

### First Modification of First Embodiment

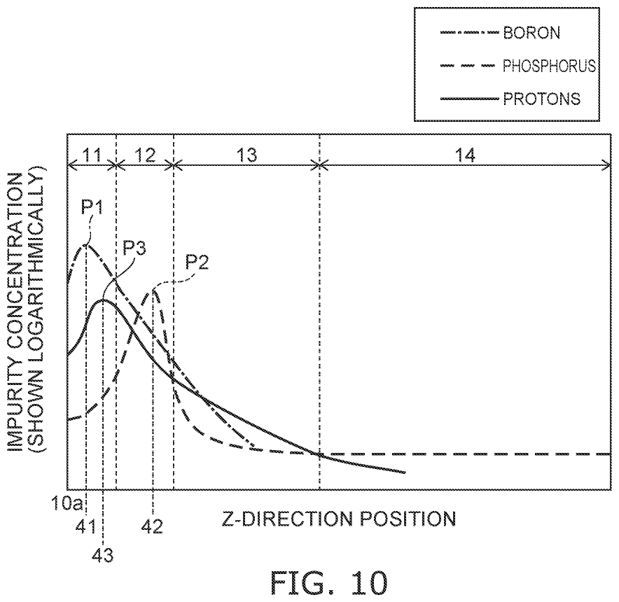

FIG. 10 shows concentration profiles along the Z-direction of impurities according to the modification, in which the horizontal axis is the Z-direction position, and the vertical axis is the concentrations of the impurities.

According to the modification as shown in FIG. 10, the peak P3 of the protons is positioned inside the p⁺-type collector layer 11. Accordingly, the position 43 at which the proton concentration has a maximum value in the Z-direction is positioned inside the p⁺-type collector layer 11. In such a case as well, effects similar to those of the embodiment described above can be obtained. Otherwise, the configuration, operations, and effects according to the modification are similar to those of the first embodiment.

### Second Modification of First Embodiment

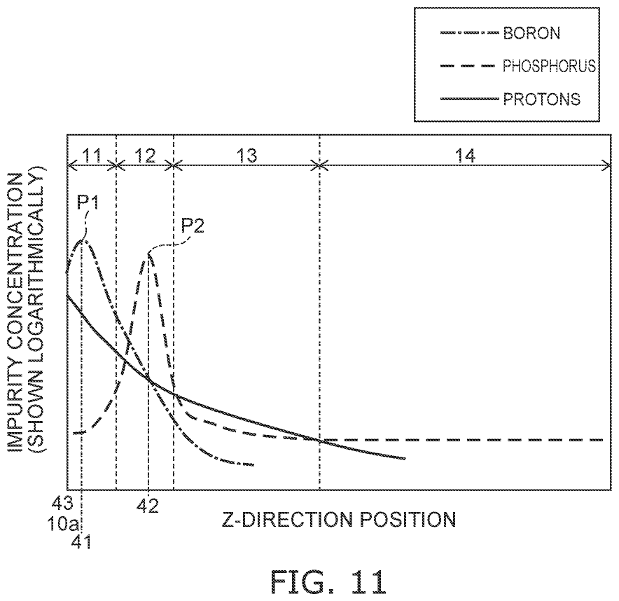

FIG. 11 shows concentration profiles along the Z-direction of impurities according to the modification, in which the horizontal axis is the Z-direction position, and the vertical axis is the concentrations of the impurities.

According to the modification as shown in FIG. 11, the proton concentration profile has no peak; and the proton concentration has a maximum value at the lower surface 10a of the semiconductor part 10, and monotonously decreases along the Z-direction. Accordingly, in the semiconductor part 10, the position 43 at which the proton concentration has a maximum value is aligned with the lower surface 10a of the semiconductor part 10.

Such a profile is realized in the process shown in FIG. 9 by implanting protons into the semiconductor part 10 via the absorber 90 so that the peak P3 of the proton concentration is positioned at the lower surface 10a of the semiconductor part 10 or inside the absorber 90, and then by removing the absorber 90. In such a case as well, effects similar to those of the embodiment described above can be obtained. Otherwise, the configuration, operations, and effects according to the modification are similar to those of the first embodiment.

### Second Embodiment

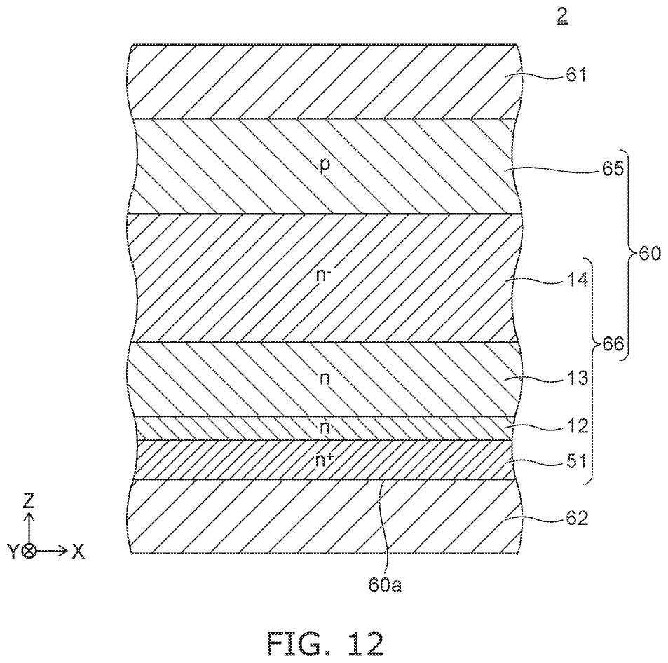

FIG. 12 is a cross-sectional view showing a semiconductor device according to the embodiment.

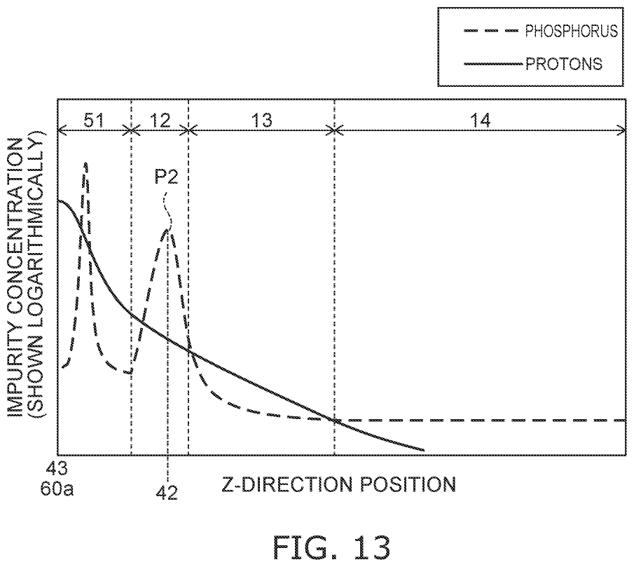

FIG. 13 shows concentration profiles along the Z-direction of the impurities according to the embodiment, in which the horizontal axis is the Z-direction position, and the vertical axis is the concentrations of the impurities.

As shown in FIG. 12, the semiconductor device 2 according to the embodiment is a p-n diode. The semiconductor device 2 includes a semiconductor part 60, an anode electrode 61, and a cathode electrode 62. The semiconductor part 60 includes a p-type part 65 and an n-type part 66; the anode electrode 61 contacts the p-type part 65; and the cathode electrode 62 contacts the n-type part 66.

The n-type part 66 includes an n⁺-type contact layer 51, the thin n-type buffer layer 12, the thick n-type buffer layer 13, and the n⁻-type base layer 14. The n⁻-type base layer 14 contacts the p-type part 65; and the n⁺-type contact layer 51 contacts the cathode electrode 62. The p⁺-type collector layer 11 is not included.

According to the embodiment as shown in FIG. 13, the proton concentration profile has no peak; and the position 43 at which the proton concentration has a maximum value in the Z-direction is aligned with a lower surface 60a of the semiconductor part 60.

Such a profile is realized by providing the absorber 90 on the lower surface 60a of the semiconductor part 60 as described with reference to FIG. 9 and by implanting protons via the absorber 90 so that the peak P3 of the proton concentration is positioned inside the absorber 90 or at the lower surface 60a when forming the thick n-type buffer layer 13. The peak P3 of the proton concentration does not remain inside the semiconductor part 60 because the absorber 90 is removed after implanting the protons.

According to the embodiment as well, the short-circuit withstand capacity can be improved because the position 43 is positioned at the cathode electrode 62 side of the position 42. Otherwise, the configuration, operations, and effects according to the embodiment are similar to those of the first embodiment described above.

### Modification of Second Embodiment

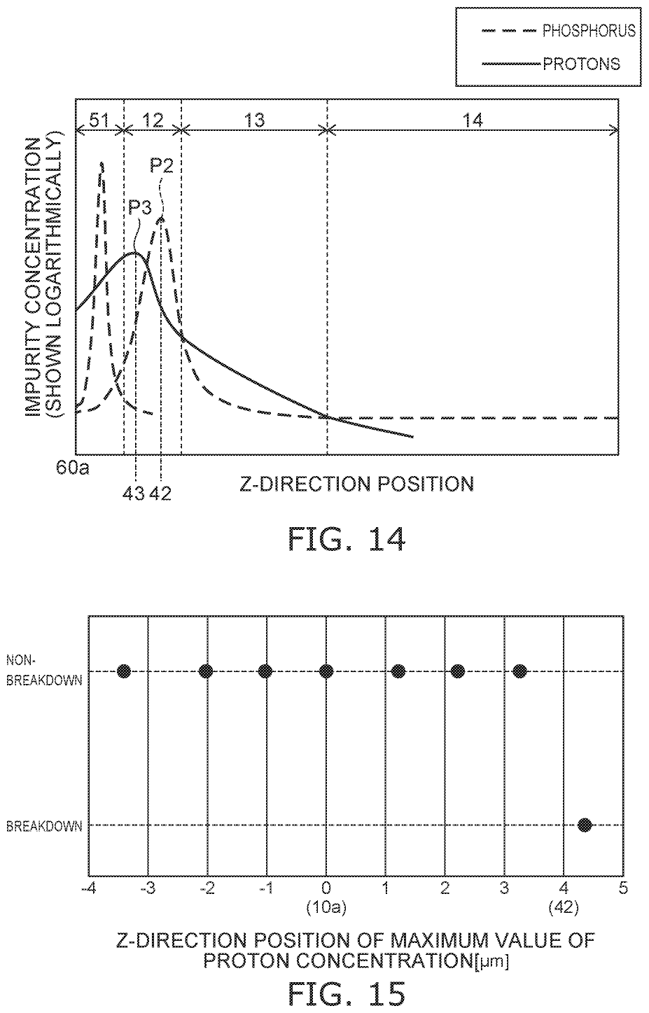

FIG. 14 shows concentration profiles along the Z-direction of impurities according to the modification, in which the horizontal axis is the Z-direction position, and the vertical axis is the concentrations of the impurities.

According to the modification as shown in FIG. 14, the position 43 of the peak P3 of the proton concentration is positioned at the cathode electrode 62 side of the position 42 of the peak P2 of the phosphorus concentration in the thin n-type buffer layer 12. The short-circuit withstand capacity can be improved thereby. Otherwise, the configuration, operations, and effects according to the modification are similar to those of the second embodiment described above.

### Test Example

FIG. 15 is a graph showing the effects of the proton profile on the short-circuit withstand capacity, in which the horizontal axis is the position at which the proton concentration has a maximum value in the Z-direction, and the vertical axis is the result of a short-circuit withstand capacity test.

The coordinate of the horizontal axis of FIG. 15 is referenced to the position of the lower surface 10a of the semiconductor part 10. In other words, “0” of the horizontal axis corresponds to the position of the lower surface 10a; negative values correspond to being outside semiconductor part 10, and specifically, inside the absorber 90; and positive values correspond to being inside the semiconductor part 10. The position 42 at which the phosphorus concentration had a maximum value was at the vicinity of +4 μm.

In the test example, multiple semiconductor devices 1 according to the first embodiment were manufactured. The position 43 at which the proton concentration had a maximum value was different between the multiple semiconductor devices 1 that were manufactured. The short-circuit withstand capacities of the semiconductor devices 1 were evaluated. The semiconductor devices that did not reach breakdown under the prescribed conditions were called “non-breakdown”; and semiconductor devices that reached breakdown were called “breakdown”.

As shown in FIG. 15, the semiconductor devices were “non-breakdown” when the position 43 at which the proton concentration had a maximum value was positioned at the −Z direction side of the position 42 at which the phosphorus concentration had a maximum value. In contrast, the semiconductor device in which the position 43 was positioned at the +Z direction side of the position 42 was “breakdown”. The semiconductor part 10 melted in the semiconductor device that reached breakdown.

An experimental example of an impurity concentration profile of an actual product will now be described.

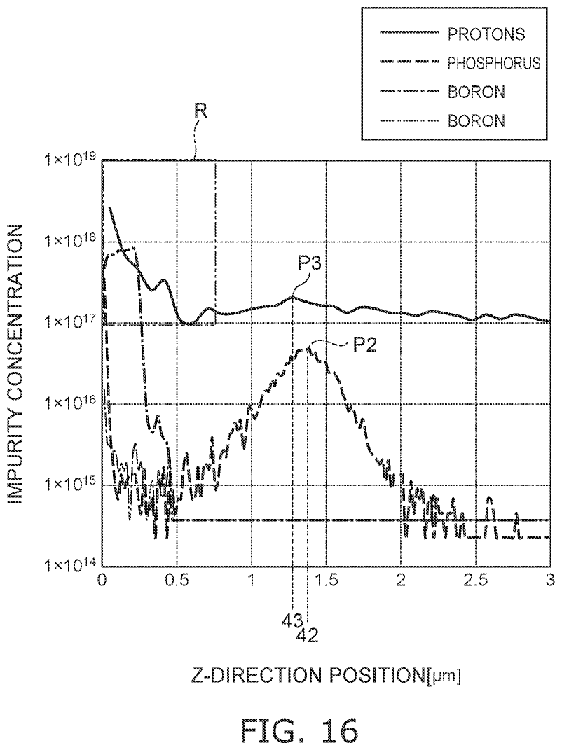

FIG. 16 shows concentration profiles along the Z-direction of the impurities in the test example, in which the horizontal axis is the Z-direction position, and the vertical axis is the concentrations of the impurities.

The concentrations of the impurities were measured by a SIMS (Secondary Ionization Mass Spectrometer).

The coordinate of the horizontal axis of FIG. 16 is referenced to the position of the lower surface 10a of the semiconductor part 10. In FIG. 16, region R was a region affected by surface adsorbates, and was therefore excluded from the following discussion.

As shown in FIG. 16, in the experimental example as well, the position 43 of the peak P3 of the proton concentration was positioned at the −Z direction side of the position 42 of the peak P2 of the phosphorus concentration. When the device was evaluated by a technique similar to the test example shown in FIG. 15, the short-circuit withstand capacity was good.

According to the embodiments described above, a semiconductor device and a method for manufacturing a semiconductor device can be realized in which the short-circuit withstand capacity is high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

Note 1 A semiconductor device, comprising:
a first electrode;
a second electrode;
a first semiconductor layer provided between the first electrode and the second electrode, the first semiconductor layer including a first impurity and protons, the first impurity and the protons forming donors, the first semiconductor layer being of an n-conductivity type, a concentration of the first impurity having a maximum value at a first position in a first direction inside the first semiconductor layer, the first direction being from the first electrode toward the second electrode;
a second semiconductor layer located at a first-direction side of the first semiconductor layer, the second semiconductor layer including the first impurity and protons, a concentration of proton being greater than the concentration of the first impurity in the second semiconductor layer, the second semiconductor layer being of the n-conductivity type; and
a third semiconductor layer located at the first-direction side of the second semiconductor layer, the third semiconductor layer including the first impurity, the concentration of the first impurity being greater than the concentration of proton in the third semiconductor layer, the third semiconductor layer being of the n-conductivity type,
the concentration of the first impurity being greater than the concentration of proton in at least a portion of the first semiconductor layer at the second semiconductor layer side,
the concentration of proton having a maximum value at a second position in the first direction, the second position being positioned at a side of the first position opposite to the first direction.

### Note 2

The device according to note 1, wherein
the second position is positioned inside the first semiconductor layer.

### Note 3

The device according to note 1, wherein
the second position is positioned at a surface of the first semiconductor layer at the first electrode side.

### Note 4

The device according to any one of notes 1-3, further comprising:
a fourth semiconductor layer of a p-conductivity type provided between the first electrode and the first semiconductor layer,
the first semiconductor layer being positioned at the first-direction side of the fourth semiconductor layer.

### Note 5

The device according to note 4, wherein
the second position is positioned inside the fourth semiconductor layer.

### Note 6

The device according to note 4, wherein
the second position is positioned at a surface of the fourth semiconductor layer at a side opposite to the first semiconductor layer.

### Note 7

The device according to any one of notes 4-6, further comprising:
a fifth semiconductor layer located at the first-direction side of the third semiconductor layer,
the fifth semiconductor layer being of the p-conductivity type.

### Note 8

The device according to note 7, further comprising:
a sixth semiconductor layer located at the first-direction side of the fifth semiconductor layer, the sixth semiconductor layer being of the n-conductivity type;
a gate electrode facing the fifth semiconductor layer; and
a gate insulating film located between the fifth semiconductor layer and the gate electrode,
the first electrode being a collector electrode connected to the fourth semiconductor layer,
the second electrode being an emitter electrode connected to the sixth semiconductor layer.

### Note 9

The device according to any one of notes 1-8, wherein
the first impurity is phosphorus.

### Note 10

A method for manufacturing a semiconductor device, the method comprising:
implanting a first impurity into a semiconductor member in a first direction from a first surface side of the semiconductor member so that a first impurity concentration has a maximum value at a first position in the first direction inside the semiconductor member, the first impurity forming donors, the semiconductor member being of an n-conductivity type;
providing an absorber at the first surface side of the semiconductor member;
implanting protons into the semiconductor member in the first direction via the absorber so that a concentration of proton has a maximum value at a second position in the first direction, the second position being positioned at a side of the first position opposite to the first direction; and
removing the absorber.

### Note 11

The method according to note 10, wherein
a target position of the second position in the first direction is set to be the first surface in the implanting of the protons.

What is claimed is:

1. A semiconductor device, comprising:
a first electrode;
a second electrode;
a first semiconductor layer provided between the first electrode and the second electrode, the first semiconductor layer including a first impurity and protons, the first impurity and the protons forming donors, the first semiconductor layer being of an n-conductivity type, a concentration of the first impurity having a maximum value at a first position in a first direction inside the first semiconductor layer, the first direction being from the first electrode toward the second electrode;
a second semiconductor layer located at a first-direction side of the first semiconductor layer, the second semiconductor layer including the first impurity and protons, a concentration of proton being greater than the concentration of the first impurity in the second semiconductor layer, the second semiconductor layer being of the n-conductivity type; and
a third semiconductor layer located at the first-direction side of the second semiconductor layer, the third semiconductor layer including the first impurity, the concentration of the first impurity being greater than the concentration of proton in the third semiconductor layer, the third semiconductor layer being of the n-conductivity type,
the concentration of the first impurity being greater than the concentration of proton in at least a portion of the first semiconductor layer at the second semiconductor layer side,
the concentration of proton having a maximum value at a second position in the first direction, the second position being positioned at a side of the first position opposite to the first direction.

2. The device according to claim 1, wherein
the second s positioned inside the first semiconductor layer.

3. The device according to claim 1, wherein
the second position is positioned at a surface of the first semiconductor layer at the first electrode side.

4. The device according to claim 1, further comprising:
a fourth semiconductor layer of a p-conductivity type provided between the first electrode and the first semiconductor layer,
the first semiconductor layer being positioned at the first-direction side of the fourth semiconductor layer.

5. The device according to claim 4, wherein
the second position is positioned inside the fourth semiconductor layer.

6. The device according to claim 4, wherein
the second position is positioned at a surface of the fourth semiconductor layer at a side opposite to the first semiconductor layer.

7. The device according to claim 4, further comprising:
a fifth semiconductor layer located at the first-direction side of the third semiconductor layer,
the fifth semiconductor layer being of the p-conductivity type.

8. The device according to claim 7, further comprising:
a sixth semiconductor layer located at the first-direction side of the fifth semiconductor layer, the sixth semiconductor layer being of the n-conductivity type;
a gate electrode facing the fifth semiconductor layer; and
a gate insulating film located between the fifth semiconductor layer and the gate electrode,
the first electrode being a collector electrode connected to the fourth semiconductor layer,
the second electrode being an emitter electrode connected to the sixth semiconductor layer.

9. The device according to claim 1, wherein
the first impurity is phosphorus.

10. A method for manufacturing a semiconductor device, the method comprising:
implanting a first impurity into a semiconductor member in a first direction from a first surface side of the semiconductor member so that a first impurity concentration has a maximum value at a first position in the first direction inside the semiconductor member, the first impurity forming donors, the semiconductor member being of an n-conductivity type;
providing an absorber at the first surface side of the semiconductor member;
implanting protons into the semiconductor member in the first direction via the absorber so that a concentration of proton has a maximum value at a second position in the first direction, the second position being positioned at a side of the first position opposite to the first direction; and
removing the absorber.

11. The method according to claim 10, wherein
a target position of the second position in the first direction is set to be the first surface in the implanting of the protons.
